(19) United States
(12) Patent Application Publication
(10) Pub. No.: US 2026/0282294 A1
(43) Pub. Date: Sep. 17, 2026

(54) SYSTEMS AND METHODS FOR DATACENTER THERMAL MANAGEMENT

(71) Applicant: Microsoft Technology Licensing, LLC, Redmond, WA (US)

(72) Inventors: Eric C. PETERSON, Woodinville, WA (US); Husam Atallah ALISSA, Redmond, WA (US); Sean Patrick ABBOTT, Redmond, WA (US)

(73) Assignee: Microsoft Technology Licensing, LLC, Redmond, WA (US)

(21) Appl. No.: 19/081,336

(22) Filed: Mar. 17, 2025

(51) Int. Cl. H05K 7/20

(52) U.S. Cl. CPC H05K 7/20827

(57) ABSTRACT

A device may include an air handling unit (AHU) including: an inlet, and an outlet, wherein the inlet and outlet define an airflow channel of the AHU. A device may include a heat exchanger positioned in the airflow channel. A device may include a thermal energy storage (TES) device in thermal communication with the heat exchanger.

### CROSS-REFERENCE TO RELATED APPLICATIONS

N/A

### BACKGROUND

Thermal management of a datacenter and the electronic devices operating therein consumes a larger quantity of energy and other resources, such as water. Conventional water-cooled systems evaporate water to the atmosphere, consuming the water from the local supply. As water supplies become strained and limited, alternative and supplemental thermal management is needed.

### SUMMARY

In some aspects, the techniques described herein relate to a device including: an air handling unit (AHU) including: an inlet, and an outlet, wherein the inlet and outlet define an airflow channel of the AHU; a heat exchanger positioned in the airflow channel; and a thermal energy storage (TES) device in thermal communication with the heat exchanger.

In some aspects, the techniques described herein relate to a datacenter including: a plurality of heat-generating electronic components; and a thermal management system configured to cool the plurality of heat-generating electronic components, the thermal management system including: a working fluid configured to receive heat from the heat-generating electronic components, and a thermal energy storage (TES) device in thermal communication with the cooling fluid and configured to receive heat from the cooling fluid.

In some aspects, the techniques described herein relate to an HVAC system including: an air handling unit (AHU) including: an inlet, an outlet, wherein the inlet and outlet define an airflow channel of the AHU, a heat exchanger positioned in the airflow channel, and a thermal energy storage (TES) device in thermal communication with the heat exchanger; and an ambient heat exchanger in thermal communication with the TES device and configured to exhaust heat from the TES device.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and aspects of embodiments of the disclosure will be set forth in the description which follows, and in part will be obvious from the description, or may be learned by the practice of such embodiments. The features and aspects of such embodiments may be realized and obtained by means of the instruments and combinations particularly pointed out in the appended claims. These and other features will become more fully apparent from the following description and appended claims or may be learned by the practice of such embodiments as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, non-schematic drawings should be considered as being to scale for some embodiments of the present disclosure, but not to scale for other embodiments contemplated herein. Understanding that the drawings depict some example embodiments, the embodiments will be described and explained with additional specificity and detail through the use of the accompanying drawings in which:

FIG. 1 is a perspective view of an embodiment of a thermal energy storage (TES) device and a heat exchanger, according to at least some embodiments of the present disclosure.

FIG. 2 is a schematic diagram of an air handling unit (AHU) with a TES device, according to at least some embodiments of the present disclosure.

FIG. 3 is a schematic diagram of an AHU with a TES device in thermal communication with an ambient heat exchanger, according to at least some embodiments of the present disclosure.

FIG. 4 is a schematic diagram of an AHU with a TES device integrated into the AHU, according to at least some embodiments of the present disclosure.

FIG. 5 is a schematic diagram of a thermal management system including an ambient heat exchanger, a TES device, and a chiller in serial thermal communication by a working fluid, according to at least some embodiments of the present disclosure.

FIG. 6 is a schematic diagram of a thermal management system where the chiller is cooling the TES device, according to at least some embodiments of the present disclosure.

FIG. 7 is a schematic diagram of a thermal management system where the chiller is bypassed, according to at least some embodiments of the present disclosure.

FIG. 8 is a schematic diagram of a thermal management system where the ambient heat exchanger is bypassed, according to at least some embodiments of the present disclosure.

FIG. 9 is a schematic diagram of a thermal management system where the ambient heat exchanger and the chiller are cooling the TES device, according to at least some embodiments of the present disclosure.

FIG. 10 is a schematic diagram of a thermal management system where the ambient heat exchanger and the TES are bypassed, according to at least some embodiments of the present disclosure.

FIG. 11 is a flowchart illustrating a machine learning model, according to at least some embodiments of the present disclosure.

### DETAILED DESCRIPTION

The present disclosure relates generally to thermal management devices. More particularly, the present disclosure relates to thermal management devices including thermal energy storage (TES) devices. In some embodiments, the TES device receives heat and stores the heat for later release into the thermal management device. In some embodiments, the TES device receives heat and stores the heat for later exhaustion outside of the thermal management device. In some embodiments, the TES device can reduce a thermal management load on another heat exchanger in the thermal management device. In some embodiments, the TES device can shift thermal management load between elements of the thermal management device. In at least one embodiment, the TES device can provide or assist in peak shaving for the thermal management device to reduce the peak energy demands of the thermal management device.

In some embodiments, the thermal management device and/or TES device is part of a heating, ventilation, and air conditioning (HVAC) system. In some embodiments, the thermal management device and/or TES device is part of a direct cooling system for a heat source. In some examples, the heat source is a plurality of heat-generating electronic components in a datacenter. For example, the thermal management device and/or TES device may be part of a liquid-cooling system that transfers heat directly from the plurality of heat-generating electronic components in the datacenter to one or more vents or heat exchangers to exhaust the heat to ambient atmosphere. In some embodiments, the thermal management device and/or TES device is part of an HVAC system of an air-cooled datacenter in which the plurality of heat-generating electronic components in the datacenter exhaust heat into the ambient air within the datacenter, and the HVAC system manages the heat in the air of the datacenter.

In some embodiments, a control plane or other computing device is in data communication with the thermal management device and/or HVAC system to control one or more pumps, valves, fans, or other control elements of the system and direct working fluid and/or air through the thermal management device and/or HVAC system. The control of the working fluid and/or air through the thermal management device and/or HVAC system may allow the control plane and/or computing device to direct heat through the thermal management device and/or HVAC system. In some embodiments, an adjustment to the flow of heat through the system is based at least partially on a temperature of a heat source (such as heat-generating electronic components). In some embodiments, an adjustment to the flow of heat through the system is based at least partially on an external temperature and/or humidity of an ambient atmosphere into which thermal management device and/or HVAC system exhausts the heat. In some embodiments, an adjustment to the flow of heat through the system is based at least partially on a temperature of a heat source (such as heat-generating electronic components). In some embodiments, an adjustment to the flow of heat through the system is based at least partially on a predictive model of one or more of the above values. For example, historical data may be provided to a machine learning (ML) model or other mathematical model that predicts a thermal management demand and/or thermal management capacity, and the control plane or other computing device may adjust the heat flow through the system based at least partially thereon.

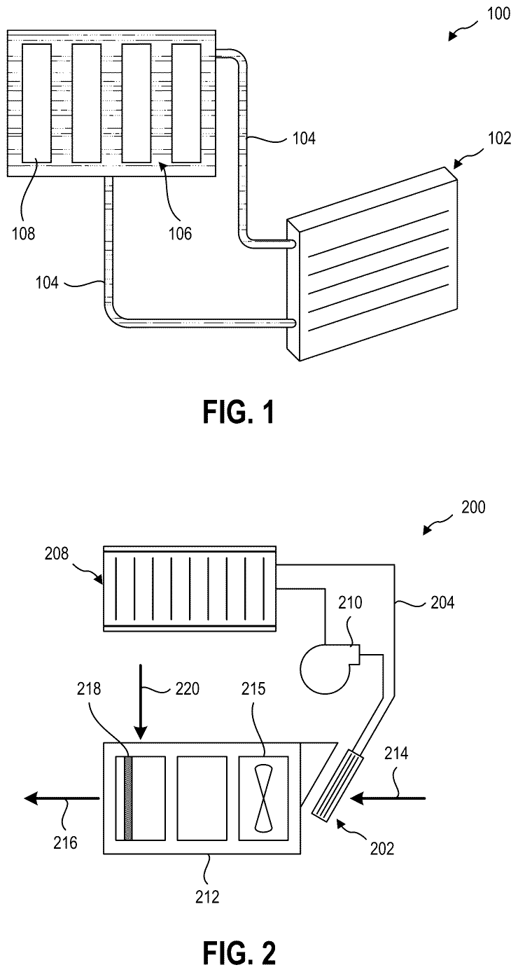

FIG. 1 is a perspective view of an embodiment of a TES device 100 and a heat exchanger 102. In some embodiments, the TES device 100 and the heat exchanger 102 are in thermal communication with one another. In some examples, a first component of a system is in thermal communication with a second component of the system when connected by a fluid conduit containing a working fluid, by a heat pipe, by a vapor chamber, by a heat spreader, or by another thermally conductive or convective element that transports heat from the first component to the second component. The first component is thermally connected to the second component when at least one element of the system is intended to physically connect the first component to the second component. In other words, and as illustrated in the embodiment of FIG. 1, a first component that receives heat from the second component only by ambient air flowing therebetween is not thermally connected, while a first component (e.g., the heat exchanger 102) connected to a second component (e.g., the TES device 100) by a fluid conduit 104 (e.g., a pipe or tube) containing a working fluid 106 therein is thermally connected when the working fluid 106 flows through the fluid conduit 104 transfers heat between the first component and the second component.

The working fluid 106 transfers heat from the heat exchanger 102 (or other heat source) to the TES device 100. In some embodiments, the TES device 100 includes a thermal mass 108 that is separate from the working fluid 106. In some embodiments, the working fluid 106 is a single-phase working fluid. For example, the working fluid 106 may remain in a single physical phase (e.g., gas, liquid) throughout the transfer of heat from the heat exchanger 102 to the TES device 100. In some embodiments, the working fluid 106 is a two-phase or multi-phase working fluid 106. For example, the working fluid 106 may change physical phase based at least partially on receiving heat from the heat exchanger 102 or other heat source. A two-phase or multi-phase working fluid may receive heat and change physical phase without substantially changing in temperature. For example, the working fluid 106 in a liquid phase may receive heat from the heat exchanger 102 or other heat source and change to a gaseous phase without increasing in temperature. In such an example, the heat received is absorbed by a latent heat of boiling of the working fluid, allowing the working fluid to receive more heat with less change in temperature.

In some embodiments, a two-phase working fluid has a boiling temperature below a target temperature of the TES device 100. For example, for a TES device 100 or other thermal management system configured to cool heat-generating electronic components, the two-phase working fluid has a boiling temperature at which heat-generating components experience thermal damage. For example, the heat-generating components may be computing components that experience damage above 100° Celsius (C). In some embodiments, the boiling temperature of the working fluid is less than about 90° C. In some embodiments, the boiling temperature of the working fluid is less than about 80° C. In some embodiments, the boiling temperature of the working fluid is less than about 70° C. In some embodiments, the boiling temperature of the working fluid is less than about 60° C. In some embodiments, the boiling temperature of the working fluid is at least about 35° C. In some embodiments, the working fluid includes water. In some embodiments, the working fluid includes glycol. In some embodiments, the working fluid includes a combination of water and glycol. In some embodiments, the working fluid is an aqueous solution. In some embodiments, the working fluid is an electronic liquid, such as FC-72 available from 3M, or similar non-conductive fluids.

In some embodiments, the thermal mass 108 is a single-phase thermal mass. For example, the thermal mass 108 may remain in a single phase during the operation of the TES device 100. In some embodiments, the TES device 100 has an operating temperature range that is based at least partially on the heat exchanger 102 or other heat source operation. For example, the TES device 100 may have any operating temperature range that is based at least partially on a predetermined amount of heat that the heat exchanger 102 is configured to receive. A single-phase thermal mass 108 remains in one phase throughout the operating temperature range of the TES device 100.

In some embodiments, the thermal mass 108 is a two-phase or multi-phase thermal mass that changes physical phase within the operating temperature range of the TES device 100. For example, the thermal mass 108 may be a phase-change material (PCM) that changes between solid and liquid phases or between liquid and gas phases in the operating temperature range of the TES device 100. In some embodiments, the thermal mass 108 is a PCM that has a melting temperature below a target temperature. In a particular example, the thermal mass 108 is a PCM configured to receive heat produced by (and therefore, cool) heat-generating electronic components in a datacenter and the melting temperature is less than a critical temperature of the heat-generating electronic components. In some examples, the thermal mass 108 has a melting temperature less than a target operating temperature of the heat-generating electronic components.

In some embodiments, the thermal mass 108 is a solid thermal mass that has a phase change temperature (i.e., melting temperature) at or less than a target temperature. In some embodiments, the thermal mass 108 is a liquid thermal mass that has a phase change temperature (i.e., boiling temperature) at or less than a target temperature. A solid thermal mass is any thermal mass that is solid in at least a portion of the operating temperature range of the TES device 100. For example, a solid thermal mass may be a single-phase thermal mass that is solid (such as a copper thermal mass) throughout the operating temperature range of the TES device 100. In some examples, a thermal mass that is solid in at least a portion of the operating temperature range of the TES device 100 is a solid thermal mass. For example, a PCM thermal mass 108 with a melting temperature of 30° C. is considered a solid thermal mass in a TES device 100 with an operating temperature range of 20° C. to 35° C.

In some embodiments, a liquid thermal mass is any thermal mass that is liquid in at least a portion of the operating temperature range of the TES device 100 and does not become solid in the operating temperature range of the TES device 100. For example, a liquid thermal mass may be a single-phase thermal mass that is liquid (such as a water thermal mass) throughout the operating temperature range of the TES device 100. In some examples, a thermal mass that is liquid in at least a portion of the operating temperature range and does not become solid in the operating temperature range of the TES device 100 is a liquid thermal mass. For example, a PCM thermal mass 108 with a boiling temperature of 30° C. is considered a liquid thermal mass in a TES device 100 with an operating temperature range of 20° C. to 35° C.

A thermal mass 108 including a PCM may allow the thermal mass 108 to receive a greater quantity of heat from the heat exchanger 102 or other heat source by receiving at least a portion of the heat as a latent heat of melting of the PCM. In some embodiments, the PCM is a paraffin wax or other wax that has a melting temperature between 20° C. and 40° C. In some embodiments, the thermal mass 108 includes a salt. In some embodiments, the thermal mass 108 includes a combination of wax and salt. In some embodiments, the thermal mass 108 includes a plurality of immiscible PCMs with different melting temperatures. During heating, the thermal mass 108 may exhibit a first temperature plateau at the melting temperature of the first PCM in the thermal mass 108 and a second temperature plateau at the melting temperature of the second PCM in the thermal mass 108.

In some embodiments, a datacenter is an air-cooled datacenter in which the heat-generating electronic components of the datacenter exhaust heat into the ambient air in the interior of the datacenter. The ambient air is subsequently conditioned (e.g., cooled, humidified, dehumidified) in the datacenter by an HVAC system. In some embodiments, the HVAC system may cool the air by transferring heat to a TES device 100 via a heat exchanger 102. In the above-described example of an air-cooled datacenter, the HVAC system may include one or more air handling units (AHUs). FIG. 2 is a schematic diagram of an embodiment of an AHU 212 with a TES device 200 in thermal communication with the AHU 212.

In some embodiments, an AHU 212 is retrofit with a TES device 200 and heat exchanger 202. In some embodiments, an AHU includes a TES device and/or heat exchanger integrated therein. In some embodiments, the AHU 212 includes an inlet 214 and an outlet 216 that define an airflow channel through the AHU 212. In some embodiments, the AHU 212 includes a fan 215 in the airflow channel to move air through the airflow channel. In some embodiments, the AHU 212 further includes an adiabatic exchanger 218 positioned in the airflow channel that cools air passing through the airflow channel by evaporative cooling. For example, the adiabatic exchanger 218 may have an evaporative media thereon that, when the air flows through the airflow channel from the inlet 214, evaporates and receives heat from the air through the latent heat of evaporation to cool the air. The cooled air then passed from the adiabatic exchanger 218 through the outlet 216 and out of the AHU 212. In some embodiments, the cooling efficiency and/or cooling capacity of the adiabatic exchanger 218 is limited by a temperature and/or humidity of the air flowing through the AHU 212. In some embodiments, the air flowing through the airflow channel is pre-cooled by a heat exchanger 202 and TES device 200 position in the airflow channel before the adiabatic exchanger 218 in the flow direction. In some embodiments, the heat exchanger 202 in thermal communication with the TES device 200 is located before the inlet 214 in the airflow channel to pre-cool air entering the inlet 214. In some embodiments, the heat exchanger 202 in thermal communication with the TES device 200 is located after the inlet 214 and before the adiabatic exchanger 218 in the airflow channel to pre-cool air entering through the inlet 214 toward the adiabatic exchanger 218. In some embodiments, the heat exchanger 202 in thermal communication with the TES device 200 is located after the adiabatic exchanger 218 and before the outlet 216 in the airflow channel to cool air exiting the adiabatic exchanger 218 when the evaporative cooling efficiency and/or effectiveness is limited. In some embodiments, the heat exchanger 202 in thermal communication with the TES device 200 is located after the adiabatic exchanger 218 and after the outlet 216 in the airflow channel to cool air exiting the outlet 216 when the evaporative cooling efficiency and/or effectiveness is limited. In some embodiments, the AHU 212 further includes a return air inlet 220 that allows air from an HVAC system to recirculate into the AHU 212 without the AHU 212 intaking external air (which may be warmer or colder than a setpoint temperature of the HVAC system and AHU 212).

The TES device 200 receives heat from the heat exchanger 202 via a working fluid flowing through fluid conduits 204 between the heat exchanger 202 and the TES device 200, such as described in relation to FIG. 1. In some embodiments, the working fluid is pumped through the fluid conduit(s) 204 by a fluid pump 210. The working fluid transfers heat from the heat exchanger 202 to the thermal mass 208 of the TES device 200. In some embodiments, the heat stored in the TES device 200 is exhausted to the ambient atmosphere.

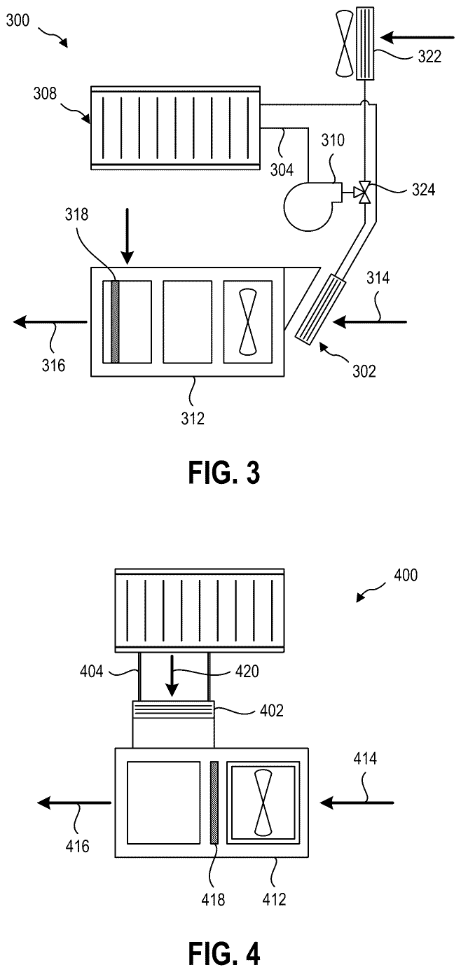

FIG. 3 is a schematic diagram of an embodiment of an AHU 312 with a TES device 300 in thermal communication with an ambient heat exchanger 322. As described in relation to FIG. 2, the heat exchanger 302 in thermal communication with the TES device 300 is positioned in an airflow channel of the AHU 312 to pre-cool (or post-cool) air flowing therethrough (e.g., into the inlet 314, past the adiabatic layer 318, and out the outlet 316). In some embodiments, the TES device 300 receives heat from the heat exchanger 302 via a working fluid flowing through fluid conduits 304 between the heat exchanger 302 and the TES device 300, such as described in relation to FIG. 1. In some embodiments, the working fluid is pumped through the fluid conduit(s) 304 by a fluid pump 310. The working fluid transfers heat from the heat exchanger 302 to the thermal mass 308 of the TES device 300. In some embodiments, the heat stored in the TES device 300 is exhausted to the ambient atmosphere.

In some embodiments, the TES device 300 and/or the heat exchanger 302 is in thermal communication with an ambient heat exchanger 322. For example, the ambient heat exchanger 322 may be located outside of a building or structure which the AHU 312 is configured to cool. The ambient heat exchanger 322 exhausts heat from the TES device 300 when a temperature of the thermal mass 308 is greater than a temperature of the ambient air flowing across the ambient heat exchanger 322. In some embodiments, the heat exchanger 302 positioned proximate to the AHU 312 directly transfers heat to the ambient heat exchanger 322 via a working fluid flowing through a fluid conduit. In some embodiments, the fluid conduit(s) 304 include one or more valves 324 to selectively control the flow of working fluid between the TES device 300 and the heat exchanger 302, between the TES device 300 and the ambient heat exchanger 322, between the heat exchanger 302 and the ambient heat exchanger 322, or combinations thereof. For example, the heat exchanger 302 may receive heat from air flowing into the AHU 312 during the day when the ambient air is warmer and direct working fluid toward the TES device 300 through the valve 324 to transfer heat to the TES device 300 and supplement the cooling capacity of the AHU 312 during the day.

Additionally, the heat exchanger 302 may receive heat from air flowing into the AHU 312 during the day and direct working fluid toward the ambient heat exchanger 322 through the valve 324 to transfer heat to the ambient heat exchanger 322 when the ambient heat exchanger 322 is exposed to air cooler than the inlet air. For example, the AHU 312 may be located in direct sunlight during portions of the day when the ambient heat exchanger 322 is located in shade, allowing heat transfer from the heat exchanger 302 to the ambient heat exchanger 322.

In some examples, the working fluid may flow from the TES device 300 to the ambient heat exchanger 322 to exhaust heat from the thermal mass 308 to the ambient atmosphere, such as at night when the cooling demands of the AHU 312 are less, and the ambient air temperature is lower. The thermal mass 308 may thereby cool down and/or change phases to “recharge” before receiving more heat from the heat exchanger 302.

FIG. 4 is a schematic diagram of an embodiment of an AHU 412 with a TES device 400 integrated into the AHU 412. In some embodiments, the AHU 412 includes a heat exchanger 402 integrated into the AHU 412 and in thermal communication with a TES device 400 to supplement the cooling of the AHU 412. In some embodiments, the heat exchanger 402 is integrated into the inlet 414 or the outlet 416. In at least one embodiment, such as that illustrated in FIG. 4, the heat exchanger 402 is integrated into the return air inlet 420 to supplement cooling of the air within the HVAC system. In some embodiments, the heat exchanger 402 is positioned to allow airflow through the return air inlet 420 and out the outlet 416 while bypassing the adiabatic exchanger 418. Such bypass can allow for cooling of the return air through the return air inlet 420 without the use of evaporative media or the adiabatic exchanger 418, which may undesirably humidify the air. For example, the fluid conduit(s) 404 may circulate a working fluid from the heat exchanger 402 to the TES device 400 to extract heat from the return air through the AHU 412 without the need of the adiabatic exchanger 418.

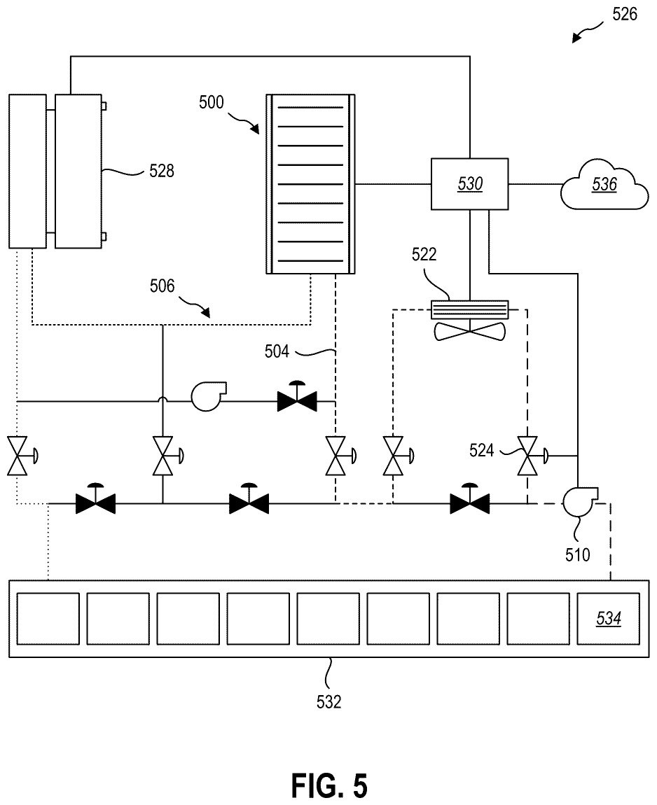

In some embodiments, the TES devices described herein may be combined with other cooling elements in an HVAC system or liquid-cooling system to provide further thermal stability to the system and/or reduce cooling loads at peak demand. FIG. 5 is a schematic diagram of an embodiment of a liquid-cooling thermal management system 526 including an ambient heat exchanger 522, a TES device 500, and a chiller 528 in serial thermal communication by a working fluid 506 flowing through a plurality of fluid conduits 504. In some embodiments, the working fluid 506 is selectively distributed and/or directed through the thermal management system 526 by a plurality of pumps 510 and valves 524. By opening, closing, or moving the valves between states, the thermal management system 526 can operate in a variety of states based on heat transfer efficiencies and/or capacities available at each of the ambient heat exchanger 522, the TES device 500, and the chiller 528 relative to a temperature of the working fluid 506.

In some embodiments, the thermal management system 526 includes a control plane 530 in communication with and/or controlling at least some of the components of the thermal management system 526. For example, the control plane 530 may be in communication with and/or controlling one or more pumps 510 and/or valves 524 in the thermal management system 526 to control the distribution and routing of working fluid 506 to the ambient heat exchanger 522, the TES device 500, the chiller 528, and combinations thereof. In some examples, the control plane 530 is in data communication with the ambient heat exchanger 522, the TES device 500, and the chiller 528 to receive temperature information, thermal capacity information, power draw, fan RPM, working fluid flow rate, and other operational information. In some embodiments, the control plane 530 is a computing device local to the thermal management system 526. In some embodiments, the control plane 530 is a computing device or plurality of computing devices located remotely to the thermal management system 526 and in communication with the thermal management system 526 via a network. In some embodiments, the control plane 530 is in data communication with an external network 536 to receive information that the control plane 530 may use to improve control of the thermal management system 526. For example, the control plane 530 may communicate with the external network 536 to receive weather information and/or forecasts, scheduling information, task allocation and/or compute load information for a datacenter in which the thermal management system 526 is located, etc.

In some examples, the thermal management system 526 is configured to cool heat-generating electronic components in a datacenter. For example, hot working fluid 506 may be received from a server rack 532 including a plurality of computing devices 534. In some embodiments, the control plane 530 is further configured to receive information from the rack 532, the computing devices 534, or other components of the datacenter to further control the thermal management system 526.

As described herein, a thermal management system 526 for liquid-cooling of computing devices 534 in a datacenter may include a TES device 500. In some embodiments, an air-cooled datacenter includes an HVAC system with one or more AHUs that each include a TES device (such as described in relation to FIG. 2 through FIG. 4). In some embodiments, a datacenter includes a thermal management system 526 including a TES device 500 for liquid-cooling of computing devices 534 and an HVAC system including one or more AHUs that each include a TES device. In some embodiments, the control plane 530 is further in data communication with an AHU of the HVAC system including a TES device for the cooling of the air in the datacenter.

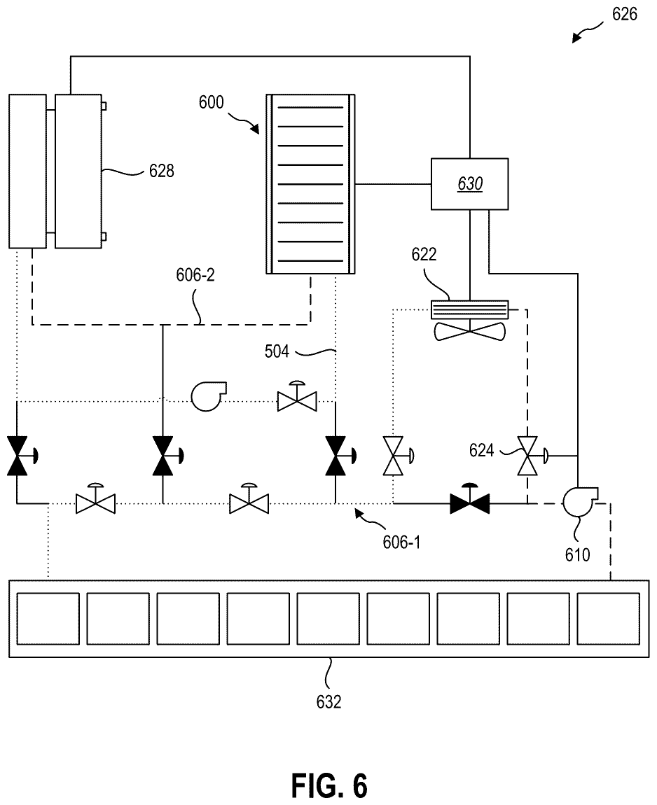

FIG. 5 through FIG. 10 illustrate different states of a thermal management system including an ambient heat exchanger, a TES device, and a chiller. In some embodiments, a state of the thermal management device includes one or more components thermally isolated from (e.g., not in thermal communication with) the other components (such as will be described in relation to FIG. 6), and the thermally isolated components may be excluded from some embodiments of a thermal management system.

Still referring to FIG. 5, in some embodiments, a pump 510 flows working fluid 506 through the fluid conduits 504 of the thermal management system 526. In some embodiments, hot working fluid 506 is received from a server rack 532 or other heat source, and the thermal management system 526 cools the working fluid 506 before returning the working fluid 506 to the server rack 532 or other heat source. In some embodiments, one or more valves 524 is selectively opened, closed, or otherwise adjusted to direct the flow of working fluid 506 through the thermal management system 526. In the illustrated embodiment of FIG. 5, the working fluid 506 is initially routed through the ambient heat exchanger 522 to exhaust heat from the hot working fluid 506. Because the ambient heat exchanger 522 exhausts the heat to ambient air, and ambient air can vary in temperature, the ambient heat exchanger 522 may only be capable of cooling the working fluid 506 by a certain amount based on the ambient temperature.

In some embodiments, the working fluid 506 is subsequently routed to the TES device 500. As described in relation to FIG. 1, the TES device 500 may further receive heat from the working fluid 506 to cool the working fluid 506 and store the heat in the thermal mass of the TES device 500. In some embodiments with a PCM thermal mass, the TES device 500 operates until the PCM thermal mass has melted to a liquid phase, as the TES device 500 will continue cooling the working fluid 506 to approximately the melting temperature of the PCM until the PCM fully changes phase. The working fluid 506 is then, in some embodiments, routed to the chiller(s) 528 that consume electricity to further cool the working fluid 506 (for example, below the melting temperature of the PCM of the TES device 500). In some embodiments, the ambient heat exchanger 522 and/or TES device 500 reduce the power consumption of the chiller 528 by pre-cooling the working fluid 506 by exhausting and/or storing the heat, respectively. In some embodiments, such peak shaving of the peak power demand of the chiller 528 can reduce costs and/or can reduce consumption of electricity or other resources. The embodiment of a state of the thermal management system 526 of FIG. 5 illustrates a serial configuration of the heat exchanger 522, the TES device 500, and the chiller 528 to provide the greatest available cooling to the working fluid 506. In other embodiments, the TES device 500 may be thermal saturated (e.g., a PCM thermal mass may be fully melted) or the ambient atmospheric temperature may be greater than the working fluid temperature, rendering the cooling capacity of the TES device 500 and the ambient heat exchanger 522 compromised. Therefore, the control plane 530 or other controller of the thermal management system 526 may reactively or proactively change states of the thermal management system 526 to bypass one or more components, recharge one or more components, or selectively disable one or more components.

FIG. 6 is a schematic diagram of an embodiment of a thermal management system 626 similar to that of FIG. 5 where the chiller 628 is cooling (“recharging”) the TES device 600. In some embodiments, the control plane 630 adjusts one or more pump 610 or valve 624 to direct flow of a first working fluid 606-1 (i.e., a first portion of the working fluid) through the ambient heat exchanger 622. In the illustrated state of the embodiment of the thermal management system 626, the ambient heat exchanger 622 is exhausting heat from the first working fluid 606-1 before the working fluid 606 is recirculated to the heat source 632. The TES device 600 and the chiller 628 are thermally isolated from the ambient heat exchanger 622 and the first working fluid 606-1. The thermal management system 626 runs the chiller 628 to cool a second working fluid 606-2 (i.e., a second portion of the working fluid) that circulates with the TES device 600. The second working fluid 606-2 cools the thermal mass of the TES device 600 to recharge the TES device 600. For example, the state of the thermal management system 626 illustrated in FIG. 6 may be a night configuration when the thermal management load from the datacenter or other heat source 632 is less, and the cooling capacity of the ambient heat exchanger 622 is greater. The thermal management system 626 may rely upon the ambient heat exchanger 622 to sufficiently cool the first working fluid 606-1 while the thermal management system operates the chiller 628 to recharge the TES device 600 in preparation period of higher thermal management demand the next day and/or higher ambient atmosphere temperatures during the day that may limit the cooling capacity of the ambient heat exchanger 622.

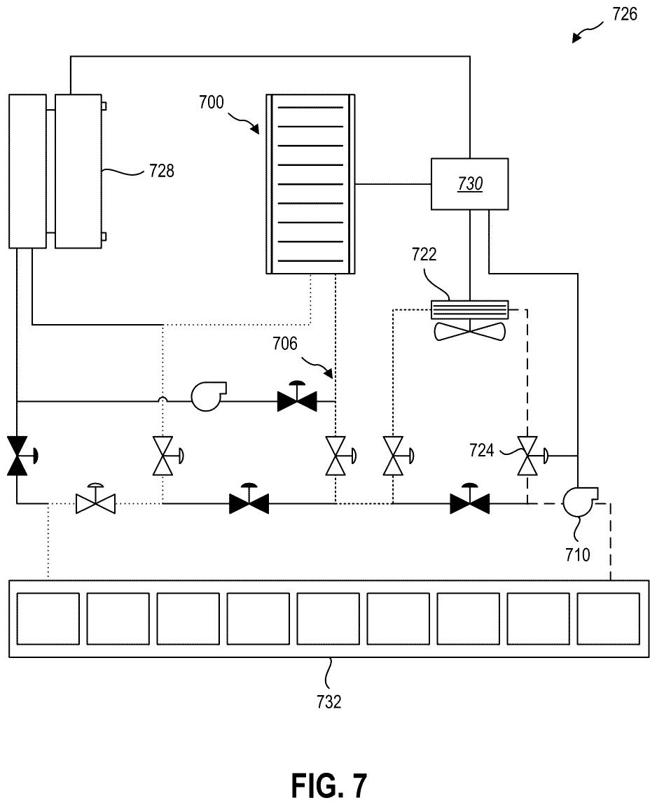

FIG. 7 is a schematic diagram of an embodiment of a thermal management system 726 similar to that of FIG. 5 where the chiller 728 is bypassed. In some embodiments, the control plane 730 adjusts one or more pump 710 or valve 724 to direct flow of a working fluid 706 through the ambient heat exchanger 722, subsequently, through the TES device 700. The ambient heat exchanger 722 cools the hot working fluid 706 received from the heat source 732 a first amount, and the TES device 700 cools the working fluid 706 received from the ambient heat exchanger 722 a second amount. In some embodiments, the TES device 700 cools the working fluid to a melting temperature of a PCM thermal mass of the TES device 700. For example, the state of the thermal management system 726 illustrated in FIG. 7 may be employed when the heat source 732 places a lesser thermal management demand on the thermal management system 726 and/or the heat source 732 requires less cooling of components therein. For example, the working fluid 706 returned to the heat source 732 in the state illustrated in FIG. 7 may be warmer than the working fluid 506 returned to the heat source 532 in the state illustrated in FIG. 5. In situations when the additional cooling of the state illustrated in FIG. 5 is not required to cool the heat source 732 (e.g., heat-generating components of a datacenter) under the current load, the state illustrated in FIG. 7 may conserve electricity and/or reduce costs by bypassing the chiller 728.

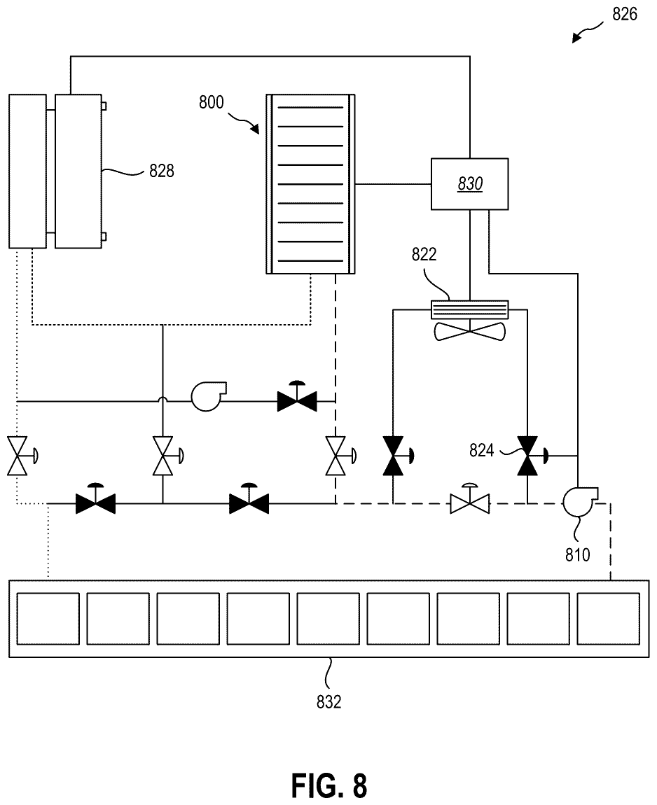

FIG. 8 is a schematic diagram of an embodiment of a thermal management system 826 similar to that of FIG. 5 where the ambient heat exchanger 822 is bypassed. In some embodiments, the control plane 830 adjusts one or more pump 810 or valve 824 to direct flow of a working fluid 806 bypassing the ambient heat exchanger 822 and to the TES device 800. For example, the control plane 830 may implement the state of the thermal management system 826 of FIG. 8 when the ambient atmospheric temperature is at or above a temperature of the hot working fluid 806 entering the thermal management system 826 from the heat source 832. In such an example, the ambient heat exchanger 822 may fail to transfer heat from the working fluid 806 (and may transfer heat to the working fluid 806), so the control plane 830 changes the state of one or more valves 824 to direct the hot working fluid 806 toward the TES device 800. The TES device 800, in some embodiments, cools to the working fluid 806 to (or toward) the melting temperature of the PCM thermal mass of the TES device 800. In some embodiments, the chiller 828 further cools to the working fluid 806 before the working fluid 806 is returned to the heat source 832. In some embodiments, the additional cooling of the chiller 828 may cause the hot working fluid 806 exiting the heat source 832 to be of a lower temperature, allowing the TES device 800 to receive heat from the working fluid 806 for a longer period of time. In other words, by cooling the working fluid 806 with the chiller 828, the TES device 800 may be able to receive heat at a lesser rate from the hot working fluid 806 for a longer period of time before the PCM thermal mass melts and the TES device 800 thermally saturates.

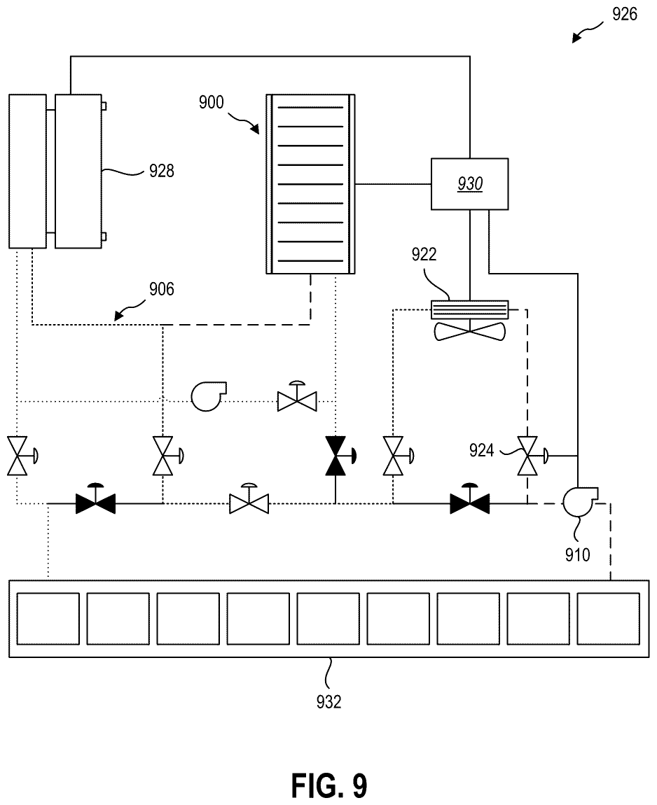

FIG. 9 is a schematic diagram of an embodiment of a thermal management system 926 similar to that of FIG. 5 where the ambient heat exchanger 922 and the chiller 928 are cooling the TES device 900. In some embodiments, the control plane 930 adjusts one or more pump 910 or valve 924 to direct flow of a working fluid 906 through the ambient heat exchanger 922 and to the chiller 928 before a portion of the working fluid 906 is directed to the TES device 900 to recharge the thermal mass of the TES device 900. For example, the TES device 900 may receive heat from a working fluid and/or thermally saturate, and the thermal management system 926 may recharge the TES device 900 by directing cold working fluid 906 toward the TES device 900 in the state of the thermal management system 926 illustrated in FIG. 9.

In some embodiments, the control plane 930 predicts a future thermal management demand and/or obtain (such as by an external network) a weather forecast, which indicates the cooling capacity of the TES device 900 to be needed in the future. The control plane 930 may direct the working fluid 906 through the ambient heat exchanger 922 to partially cool the working fluid 906 from the heat source 932 and, subsequently, through the chiller 928 to fully cool the working fluid 906. At least a portion of the cold working fluid is circulated through the TES device 900 to recharge the TES device 900 before being routed back to the chiller 928 to be cooled again. In such an example, the TES device 900 may be recharged while both the ambient heat exchanger 922 and the chiller 928 operate to cool the working fluid 906.

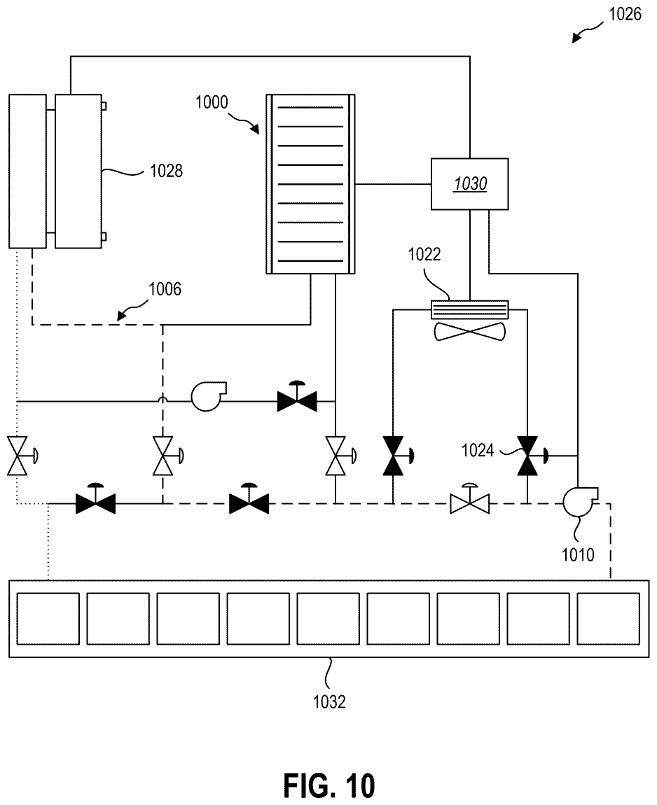

FIG. 10 is a schematic diagram of an embodiment of a thermal management system 1026 similar to that of FIG. 5 where the ambient heat exchanger 1022 and the TES device 1000 are bypassed. In some embodiments, the ambient atmospheric temperature is at or greater than the temperature of the hot working fluid 1006 from the heat source 1032, and the TES device 1000 is thermally saturated (or the thermal capacity of which may be needed at a later time). In such examples, the control plane 1030 adjusts one or more pump 1010 or valve 1024 to direct flow of a working fluid 1006 bypassing the ambient heat exchanger 1022 and the TES device 100 to flow directly to the chiller 1028.

As described herein, the control plane 1030 may make changes to the state of the thermal management system 1026 reactively to the state of the datacenter, the thermal management system 1026, or the ambient atmosphere/weather. In some embodiments, the control plane 1030 makes changes to the state of the thermal management system 1026 proactively based on predictions of the state of the datacenter, the thermal management system 1026, or the ambient atmosphere/weather. In some embodiments, the predictions or forecasts are obtained via an external network, such as described in relation to FIG. 5. In some embodiments, the predictions or forecasts are based on a mathematical model and/or machine-learning (ML) model.

In some embodiments, the control plane 1030 makes changes to the state of the thermal management system 1026 based on a predicted thermal management demand. In some embodiments, the control plane 1030 makes changes to the state of the thermal management system 1026 based on a predicted compute load of the computing devices in the datacenter. In some embodiments, the control plane 1030 makes changes to the state of the thermal management system 1026 based on a predicted thermal capacity (such as TES device thermal capacity or ambient heat exchanger capacity). In some embodiments, the control plane 1030 makes changes to the state of the thermal management system 1026 based on a predicted environmental factors, such as weather. For example, the predicted environmental factors may include an ambient atmospheric temperature, ambient atmospheric humidity, cloud cover, angle of sun, or any other environmental factors that affect the heat transfer rate or capacity of the ambient heat exchanger. In some embodiments, the control plane 1030 makes changes to the state of the thermal management system 1026 based on a predicted electrical cost and/or availability. As describe herein, a TES device 1000 may allow the thermal management system to reduce load on the chillers 1028 and, therefore, reduce peak consumption rates of electricity. In some embodiments, electricity costs vary by time of day, day of the week, or with grid source variations.

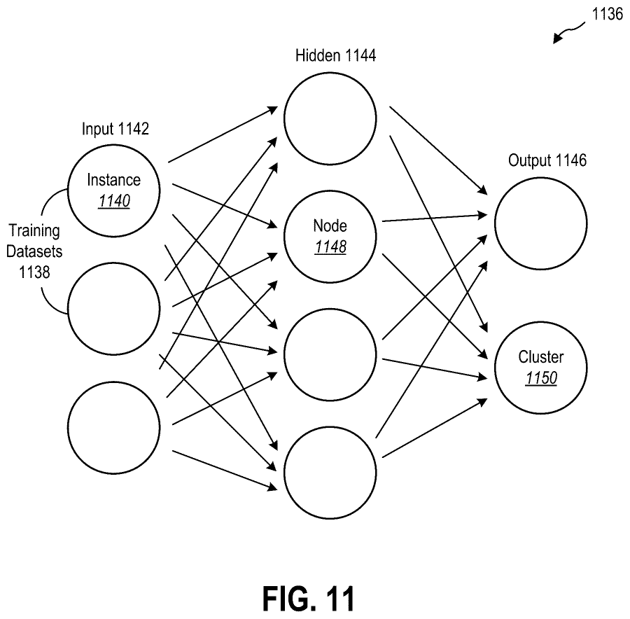

FIG. 11 is a flowchart illustrating an embodiment of an ML model 1136 that may be used to determine one or more predicted values for the control plane to change a state of the thermal management system. As used herein, a “machine learning model” refers to a computer algorithm or model (e.g., a classification model, a regression model, a language model, an object detection model) that can be tuned (e.g., trained) based on training input to approximate unknown functions. For example, an ML model may refer to a neural network or other machine learning algorithm or architecture that learns and approximates complex functions and generate outputs based on a plurality of inputs provided to the machine learning model. In some embodiments, an ML system, model, or neural network described herein is an artificial neural network. In some embodiments, an ML system, model, or neural network described herein is a convolutional neural network. In some embodiments, an ML system, model, or neural network described herein is a recurrent neural network. In at least one embodiment, an ML system, model, or neural network described herein is a Bayes classifier. As used herein, a “machine learning system” may refer to one or multiple ML models that cooperatively generate one or more outputs based on corresponding inputs. For example, an ML system may refer to any system architecture having multiple discrete ML components that consider different kinds of information or inputs. As used herein, an “instance” refers to an input object that may be provided as an input to an ML system to use in generating an output.

In some embodiments, the machine learning system has a plurality of layers with an input layer 1142 configured to receive at least one input training dataset 1138 or input training instance 1140 and an output layer 1146, with a plurality of additional or hidden layers 1144 therebetween. The training datasets can be input into the machine learning system to train the machine learning system and identify individual and combinations of labels or attributes of the training instances that allow the machine learning model to improve recognition and/or measurement of target ion concentration. In some embodiments, the machine learning system can receive multiple training datasets concurrently and learn from the different training datasets simultaneously.

In some embodiments, the machine learning system includes a plurality of machine learning models that operate together. Each of the machine learning models has a plurality of hidden layers between the input layer and the output layer. The hidden layers have a plurality of input nodes (e.g., nodes 1148), where each of the nodes operates on the received inputs from the previous layer. In a specific example, a first hidden layer has a plurality of nodes and each of the nodes performs an operation on each instance from the input layer. Each node of the first hidden layer provides a new input into each node of the second hidden layer, which, in turn, performs a new operation on each of those inputs. The nodes of the second hidden layer then passes outputs, such as identified clusters 1150, to the output layer.

In some embodiments, each of the nodes 1148 has a linear function and an activation function. The linear function may attempt to optimize or approximate a solution with a line of best fit. The activation function operates as a test to check the validity of the linear function. In some embodiments, the activation function produces a binary output that determines whether the output of the linear function is passed to the next layer of the machine learning model. In this way, the machine learning system can limit and/or prevent the propagation of poor fits to the data and/or non-convergent solutions.

The machine learning model includes an input layer that receives at least one training dataset. In some embodiments, at least one machine learning model uses supervised training. In some embodiments, at least one machine learning model uses unsupervised training. Unsupervised training can be used to draw inferences and find patterns or associations from the training dataset(s) without known outputs. In some embodiments, unsupervised learning can identify clusters of similar labels or characteristics for a variety of training instances and allow the machine learning system to extrapolate the performance of instances with similar characteristics.

In some embodiments, semi-supervised learning can combine benefits from supervised learning and unsupervised learning. As described herein, the machine learning system can identify associated labels or characteristic between instances, which may allow a training dataset with known outputs and a second training dataset including more general input information to be fused. Unsupervised training can allow the machine learning system to cluster the instances from the second training dataset without known outputs and associate the clusters with known outputs from the first training dataset.

The present disclosure relates generally to devices and systems for providing thermal management according to any of the clauses herein:

Clause 1. A device comprising: an air handling unit (AHU) including: an inlet, and an outlet, wherein the inlet and outlet define an airflow channel of the AHU; a heat exchanger positioned in the airflow channel; and a thermal energy storage (TES) device in thermal communication with the heat exchanger.

Clause 2. The device of clause 1, further comprising a working fluid configured to transfer heat between the heat exchanger and the thermal energy storage.

Clause 3. The device of clause 2, wherein the TES device includes a solid thermal mass configured to receive heat from the working fluid.

Clause 4. The device of clause 3, wherein the solid thermal mass is a phase change material (PCM) has a melting temperature in a range of 20° C. to 40° C.

Clause 5. The device of clause 3, wherein the solid thermal mass includes a wax.

Clause 6. The device of clause 3, wherein the solid thermal mass includes a first PCM phase with a first melting temperature and a second PCM phase with a second melting temperature, and the first PCM phase and second PCM phase are immiscible with one another.

Clause 7. The device of clause 2, wherein the working fluid is a two-phase working fluid.

Clause 8. The device of clause 1, wherein the heat exchanger is positioned proximate to the inlet of the AHU.

Clause 9. The device of clause 1, wherein AHU further includes an adiabatic exchanger in the airflow channel, and the heat exchanger is positioned in the AHU before an adiabatic exchanger of the AHU in a flow direction.

Clause 10. The device of clause 9, wherein the adiabatic exchanger is an evaporative media exchanger.

Clause 11. A datacenter comprising: a plurality of heat-generating electronic components; and a thermal management system configured to cool the plurality of heat-generating electronic components, the thermal management system including: a working fluid configured to receive heat from the heat-generating electronic components, and a thermal energy storage (TES) device in thermal communication with the cooling fluid and configured to receive heat from the cooling fluid.

Clause 12. The datacenter of clause 11, further comprising an ambient heat exchanger in thermal communication with the TES device.

Clause 13. The datacenter of clause 12, further comprising a chiller in thermal communication with the TES device.

Clause 14. The datacenter of clause 13, further comprising a control plane in data communication with the ambient heat exchanger, the TES device, the chiller, and at least one valve to selectively route the working fluid between the ambient heat exchanger, the TES device, and the chiller.

Clause 15. The datacenter of clause 14, wherein the control plane is configured to selectively route the working fluid based at least partially on an external ambient atmospheric temperature.

Clause 16. The datacenter of clause 14, wherein the control plane is configured to selectively route the working fluid based at least partially on a temperature of the TES device.

Clause 17. The datacenter of clause 14, wherein the control plane is configured to selectively route the working fluid based at least partially on a predicted thermal management demand.

Clause 18. The datacenter of clause 14, wherein the control plane is configured to selectively route the working fluid based at least partially on predicted weather conditions.

Clause 19. The datacenter of clause 14, wherein the control plane is configured to predict one or more values to change a state of the thermal management system using a machine learning model.

Clause 20. An HVAC system comprising: an air handling unit (AHU) including: an inlet, an outlet, wherein the inlet and outlet define an airflow channel of the AHU, a heat exchanger positioned in the airflow channel, and a thermal energy storage (TES) device in thermal communication with the heat exchanger; and an ambient heat exchanger in thermal communication with the TES device and configured to exhaust heat from the TES device.

It should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein, to the extent such features are not described as being mutually exclusive. Numbers, percentages, ratios, or other values stated herein are intended to include that value, and also other values that are “about”, “substantially”, or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

The terms “approximately,” “about,” and “substantially” as used herein represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims. The described embodiments are therefore to be considered as illustrative and not restrictive, and the scope of the disclosure is indicated by the appended claims rather than by the foregoing description.

What is claimed is:

1. A device comprising:
an air handling unit (AHU) including:
an inlet, and
an outlet, wherein the inlet and outlet define an airflow channel of the AHU;
a heat exchanger positioned in the airflow channel; and
a thermal energy storage (TES) device in thermal communication with the heat exchanger.

2. The device of claim 1, further comprising a working fluid configured to transfer heat between the heat exchanger and the thermal energy storage.

3. The device of claim 2, wherein the TES device includes a solid thermal mass configured to receive heat from the working fluid.

4. The device of claim 3, wherein the solid thermal mass is a phase change material (PCM) has a melting temperature in a range of 20° C. to 40° C.

5. The device of claim 3, wherein the solid thermal mass includes a wax, a salt, or a combination thereof.

6. The device of claim 3, wherein the solid thermal mass includes a first PCM phase with a first melting temperature and a second PCM phase with a second melting temperature, and the first PCM phase and second PCM phase are immiscible with one another.

7. The device of claim 2, wherein the working fluid is a two-phase working fluid.

8. The device of claim 1, wherein the heat exchanger is positioned proximate to the inlet of the AHU.

9. The device of claim 1, wherein AHU further includes an adiabatic exchanger in the airflow channel, and the heat exchanger is positioned in the AHU before an adiabatic exchanger of the AHU in a flow direction.

10. The device of claim 9, wherein the adiabatic exchanger is an evaporative media exchanger.

11. A datacenter comprising:
a plurality of heat-generating electronic components; and
a thermal management system configured to cool the plurality of heat-generating electronic components, the thermal management system including:
a working fluid configured to receive heat from the heat-generating electronic components, and
a thermal energy storage (TES) device in thermal communication with the cooling fluid and configured to receive heat from the cooling fluid.

12. The datacenter of claim 11, further comprising an ambient heat exchanger in thermal communication with the TES device.

13. The datacenter of claim 12, further comprising a chiller in thermal communication with the TES device.

14. The datacenter of claim 13, further comprising a control plane in data communication with the ambient heat exchanger, the TES device, the chiller, and at least one valve to selectively route the working fluid between the ambient heat exchanger, the TES device, and the chiller.

15. The datacenter of claim 14, wherein the control plane is configured to selectively route the working fluid based at least partially on an external ambient atmospheric temperature.

16. The datacenter of claim 14, wherein the control plane is configured to selectively route the working fluid based at least partially on a temperature of the TES device.

17. The datacenter of claim 14, wherein the control plane is configured to selectively route the working fluid based at least partially on a predicted thermal management demand.

18. The datacenter of claim 14, wherein the control plane is configured to selectively route the working fluid based at least partially on predicted weather conditions.

19. The datacenter of claim 14, wherein the control plane is configured to predict one or more values to change a state of the thermal management system using a machine learning model.

20. An HVAC system comprising:
an air handling unit (AHU) including:
an inlet,
an outlet, wherein the inlet and outlet define an airflow channel of the AHU,
a heat exchanger positioned in the airflow channel, and
a thermal energy storage (TES) device in thermal communication with the heat exchanger; and
an ambient heat exchanger in thermal communication with the TES device and configured to exhaust heat from the TES device.
